(19) United States
(12) Patent Application Publication
(10) Pub. No.: US 2026/0271235 A1
(43) Pub. Date: Sep. 10, 2026

(54) HEAT PIPE AND ELECTRICAL DEVICE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Jo SUGIURA, Osaka (JP); Hideyuki KUBOKI, Osaka (JP)

(21) Appl. No.: 19/167,843

(22) PCT Filed: Mar. 15, 2024
(86) PCT No.: PCT/JP2024/010202

§ 371 Date: Sep. 23, 2025

(30) Foreign Application Priority Data
Mar. 31, 2023 (JP) 2023-058181

(51) Int. Cl. H05K 7/20; H02G 5/10

(52) U.S. Cl. CPC H05K 7/20336; H02G 5/10; H05K 7/20409

(57) ABSTRACT

A heat pipe 10 is disposed inside an electrical appliance 1 and is attached to an object, the heat pipe 10 comprising: a bottom portion 11 having a contact surface 13 in contact with the object; a peripheral wall portion 12 extending from the bottom portion 11 in a direction intersecting the contact surface 13; a sealed space 14 formed inside the bottom portion 11 and the peripheral wall portion 12; and a working fluid 15 disposed so as to occupy a portion of the sealed space 14.

### TECHNICAL FIELD

The present disclosure relates to a heat pipe and an electrical device.

### BACKGROUND

Electrical devices installed in vehicles such as electric automobiles and hybrid automobiles include a component that easily generates heat, and a configuration for causing such a component to dissipate the heat is provided. As such a configuration, the heat dissipation structure of a semiconductor circuit breaker described in JP 2016-018924 A (Patent Document 1 below) is conventionally known. The heat dissipation structure of a semiconductor circuit breaker is a structure that dissipates heat generated by a semiconductor circuit breaker that turns on and off to interrupt and conduct a current flow between specified objects, and the heat dissipation structure is provided with a metal busbar on which the semiconductor circuit breaker is mounted and a metal heat pipe provided in contact with the busbar. The heat pipe is connected to a heat dissipation member on the end side opposite to the end side on which it is in contact with the busbar. Examples of the heat dissipation member include a battery pack cover and a car body.

### PRIOR ART DOCUMENT

### Patent Document

Patent Document 1: JP 2016-018924 A

### SUMMARY OF THE INVENTION

### Problems to be Solved

When the above-described heat dissipation structure of a semiconductor circuit breaker is installed in a vehicle, and the vehicle is inclined on a slope or the like, a working fluid inside a heat pipe may be placed unevenly and biased toward the end on the heat dissipation member side of the heat pipe, and there may be little working fluid on the busbar side of the heat pipe. In such a case, it may be difficult for the heat generated in the semiconductor circuit breaker to be efficiently absorbed by vaporization of the working fluid.

### Means to Solve the Problem

The heat pipe according to the present disclosure is a heat pipe configured to be disposed inside an electrical device and to be attached to an object, the heat pipe including: a bottom that has a contact surface configured to come into contact with the object; a circumferential wall portion that extends from the bottom in a direction that intersects the contact surface; a sealed space formed inside the bottom and the circumferential wall portion; and a working fluid placed to fill a part of the sealed space.

Also, the electrical device according to the present disclosure is an electrical device that includes: the above-described heat pipe; a heat generation component; and a busbar that is connected to the heat generation component and to which the heat pipe is attached.

### Effect of the Invention

According to the present disclosure, it is possible to provide a heat pipe and an electrical device that can efficiently dissipate heat of an object.

### BRIEF DESCRIPTION OF THE DRAWINGS

FIG. 1 is a perspective view showing the main portion of an electrical device according to Embodiment 1.

FIG. 2 is a perspective view of a heat pipe.

FIG. 3 is a perspective view of the heat pipe before an introduction tube is sealed.

FIG. 4 is a cross-sectional view taken along a line A-A in FIG. 2.

FIG. 5 is a cross-sectional view taken along a line B-B in FIG. 4.

FIG. 6 is a cross-sectional view taken along a line C-C in FIG. 4.

FIG. 7 is a cross-sectional view taken along a line D-D in FIG. 4.

FIG. 8 is a cross-sectional view showing the arrangement of a working fluid with the electrical device placed on a horizontal plane.

FIG. 9 is a cross-sectional view showing placement of the working fluid with the electrical device inclined.

FIG. 10 is a perspective view showing a heat pipe according to Embodiment 2.

FIG. 11 is a cross-sectional view of FIG. 10, corresponding to FIG. 4 of Embodiment 1.

FIG. 12 is a cross-sectional view of FIG. 10, corresponding to FIG. 7 of Embodiment 1.

FIG. 13 is a cross-sectional view showing a state where the heat pipe is attached to a busbar.

FIG. 14 is a perspective view showing a heat pipe according to Embodiment 3.

FIG. 15 shows the heat pipe viewed from one side in a first direction.

FIG. 16 is a cross-sectional view of the heat pipe, corresponding to FIG. 4 of Embodiment 1.

FIG. 17 is a perspective view showing a heat pipe according to Embodiment 4.

FIG. 18 is a cross-sectional view of the heat pipe, corresponding to FIG. 4 of Embodiment 1.

FIG. 19 is a perspective view showing a heat pipe according to Embodiment 5.

FIG. 20 is a cross-sectional view of the heat pipe, corresponding to FIG. 4 of Embodiment 1.

### DETAILED DESCRIPTION TO EXECUTE THE INVENTION

### Description of Embodiments of Present Disclosure

First, embodiments of the present disclosure will be listed and described.
[1] The heat pipe according to the present disclosure is a heat pipe configured to be disposed inside an electrical device and to be attached to an object, the heat pipe including: a bottom that has a contact surface configured to come into contact with the object; a circumferential wall portion that extends from the bottom in a direction that intersects the contact surface; a sealed space formed inside the bottom and the circumferential wall portion; and a working fluid placed to fill a part of the sealed space.

With this configuration, even if the electrical device is inclined, at least a part of the working fluid is easily placed to come into contact with the bottom, thus facilitating heat transfer from the object to the working fluid. Therefore, the heat of the object can be efficiently dissipated by vaporization of the working fluid.
[2] The heat pipe according to [1] above preferably further includes a plurality of fins that extend from the circumferential wall portion.

With this configuration, providing the fins facilitates dissipation of heat from the heat pipe to ambient air.
[3] In the heat pipe according to [1] or [2] above, preferably, the bottom is circular, and the circumferential wall portion extends from an outer edge of the bottom.

With this configuration, at least a part of the working fluid is easily placed to come into contact with the bottom, regardless of the direction in which the electrical device is inclined. Therefore, the heat of the object can be dissipated more efficiently.
[4] In the heat pipe according to any one of [1] to [3] above, preferably, the bottom has an insertion hole for bolting the heat pipe to the object.

With this configuration, it is possible to attach the heat pipe to the object by bolting.
[5] In the heat pipe according to any one of [1] to [4] above, preferably, the circumferential wall portion is located above the bottom when the electrical device is disposed on a horizontal plane.

With this configuration, it is possible to maximize the volume of the working fluid placed to come into contact with the bottom when the electrical device is not inclined. Therefore, the heat of the object can be dissipated more efficiently.
[6] An electrical device according to the present disclosure includes: the heat pipe according to any one of [1] to [5] above; a heat generation component; and a busbar that is connected to the heat generation component and to which the heat pipe is attached.

With this configuration, it is possible to efficiently dissipate heat transferred from the heat generation component to the busbar.

### Detail of Embodiments of Present Disclosure

The following will describe embodiments of the present disclosure. The present disclosure is not limited to the examples but is indicated by the claims, and is intended to include all modifications within the meaning and scope equivalent to the claims. In the drawings, the configurations may be partially exaggerated or simplified for convenience in the description. Also, the dimensional ratios of various portions may differ among the drawings. When there are a plurality of members that are the same, reference numerals may be given to some of the members and not to the other members. In the context of the present specification, the terms “orthogonal” and “parallel” include not only exactly orthogonal and parallel, but also substantially orthogonal and parallel to the extent that the functions and effects of the embodiments are achieved.

### Embodiment 1

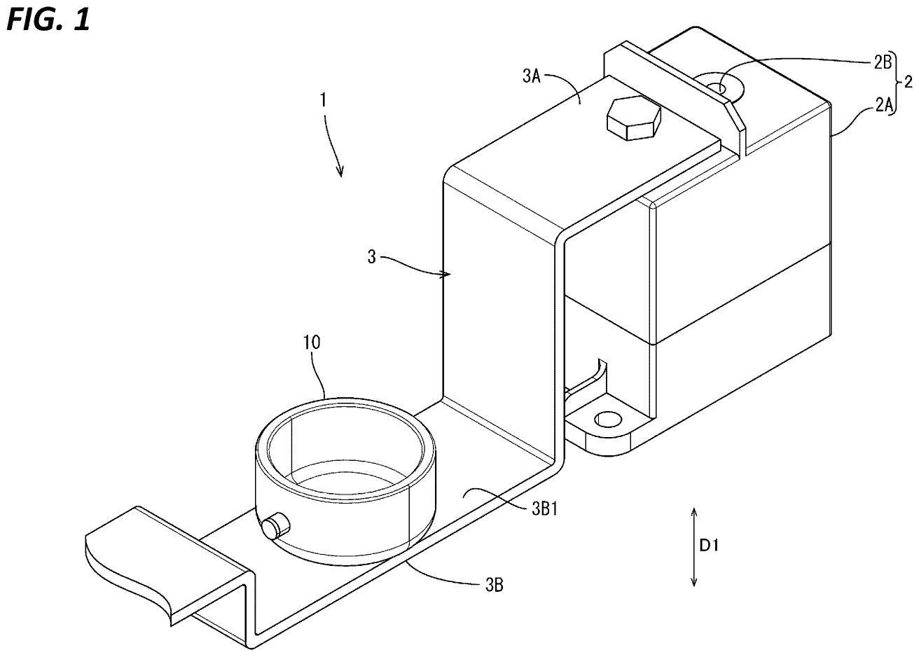

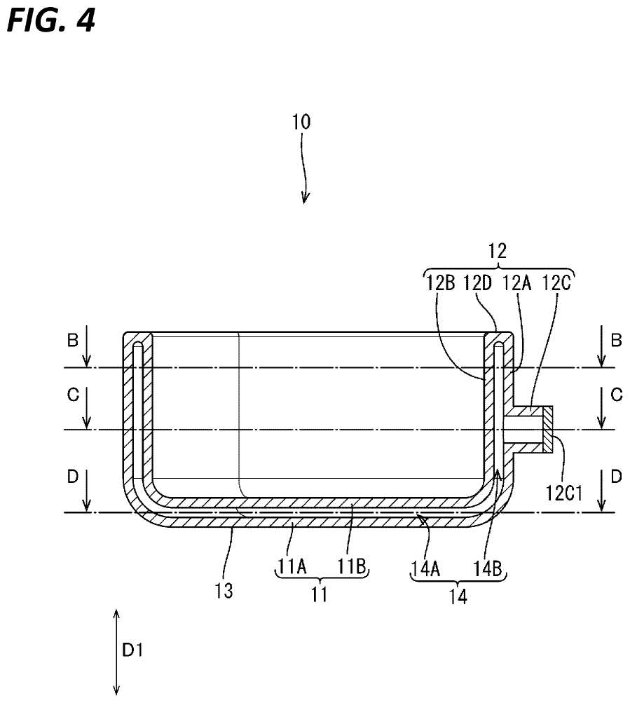

The following will describe Embodiment 1 of the present disclosure with reference to FIGS. 1 to 9. An electrical device 1 provided with a heat pipe 10 according to the present embodiment is installed, for example, in a vehicle such as an electric automobile or a hybrid automobile, and is disposed in a power supply path that connects a power source such as a battery and a load such as a motor. In the following description, the direction orthogonal to a contact surface 13 of the heat pipe 10 is defined as a first direction D1 (see FIG. 4), and any direction orthogonal to the first direction D1 is defined as an in-plane direction.

### Electrical Device 1

As shown in FIG. 1, the electrical device 1 includes a relay 2 (an example of a heat generation member), a busbar 3 (an example of an object) connected to the relay 2, and a heat pipe 10 attached to the busbar 3. The electrical device 1 also includes a case (not shown) that houses the relay 2, the busbar 3, and the heat pipe 10.

### Relay 2 and Busbar 3

The relay 2 includes a block-shaped body part 2A and a terminal part 2B. The terminal part 2B has, for example, a fastening hole for bolting the busbar 3. The busbar 3 is made of a conductive metal plate material. The busbar 3 includes a connection part 3A electrically connected to the relay 2 and a mounting part 3B to which the heat pipe 10 is attached. The connection part 3A is connected to the terminal part 2B by bolting, for example. The mounting part 3B is flat with respect to the first direction D1. The mounting part 3B has an outer surface 3B1 that is in contact with the heat pipe 10. The outer surface 3B1 is a surface arranged on one side of the mounting part 3B in the first direction D1 and is orthogonal to the first direction D1. In order to efficiently dissipate heat generated by the relay 2, the mounting part 3B is preferably located near the connection part 3A.

### Heat Pipe 10

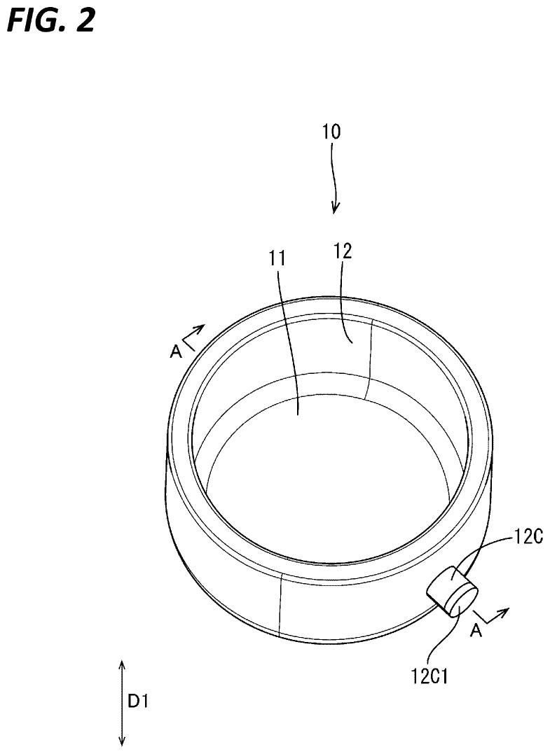

The heat pipe 10 is made of metal. As shown in FIG. 2, the heat pipe 10 includes a bottom 11 and a circumferential wall portion 12 that extends from the outer edge of the bottom 11 to one side in the first direction D1.

### Bottom 11, Circumferential Wall Portion 12, and Contact Surface 13

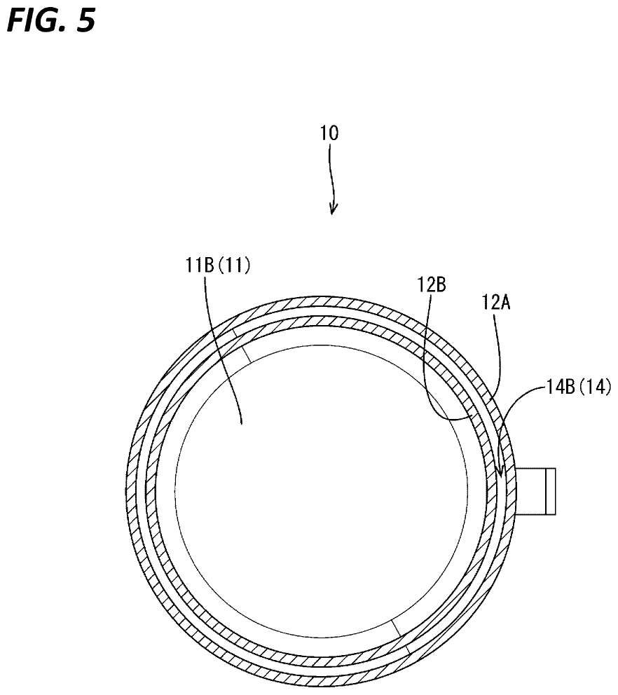

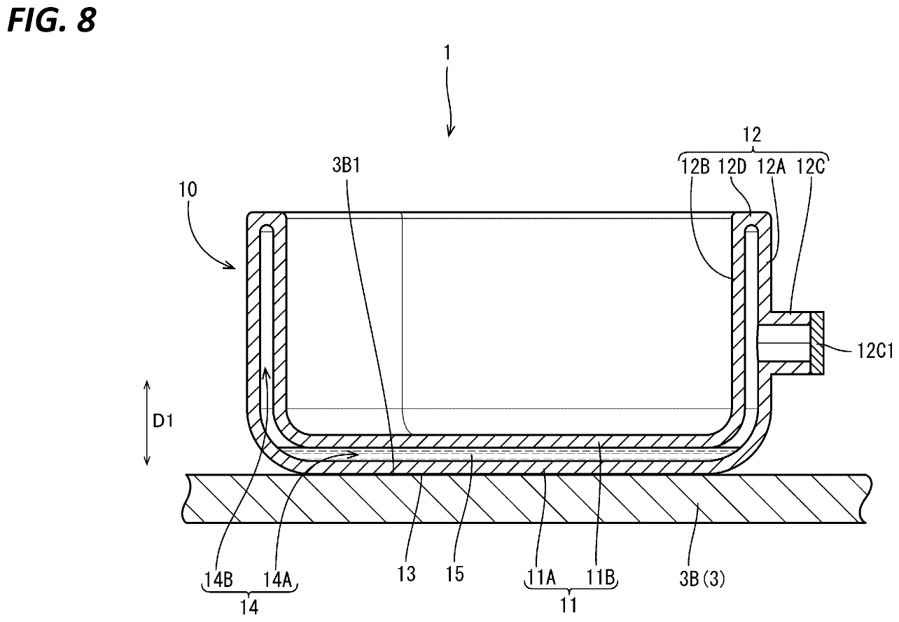

The bottom 11 is circular when viewed in the first direction D1 (see FIGS. 5 to 7). As shown in FIG. 4, the bottom 11 has a first wall 11A and a second wall 11B arranged on one side (upper side in the illustration of FIG. 4) of the first wall 11A in the first direction D1. The circumferential wall portion 12 has an outer wall 12A continuous with an end of the first wall 11A in the in-plane direction, an inner wall 12B continuous with an end of the second wall 11B in the in-plane direction, and a cylindrical tubular portion 12C that extends from the outer wall 12A. The ends of the outer wall 12A and the inner wall 12B on one side in the first direction D1 are connected to each other by a connection end 12D. The end of the tubular portion 12C in the direction away from the inner wall 12B in the in-plane direction is sealed by a sealing part 12C1. As shown in FIG. 8, the first wall 11A has a contact surface 13 that is in contact with an outer surface 3B1 of the mounting part 3B of the busbar 3. The contact surface 13 is fixed to the outer surface 3B1, for example, by bonding using an adhesive, welding, or other methods.

### Sealed Space 14

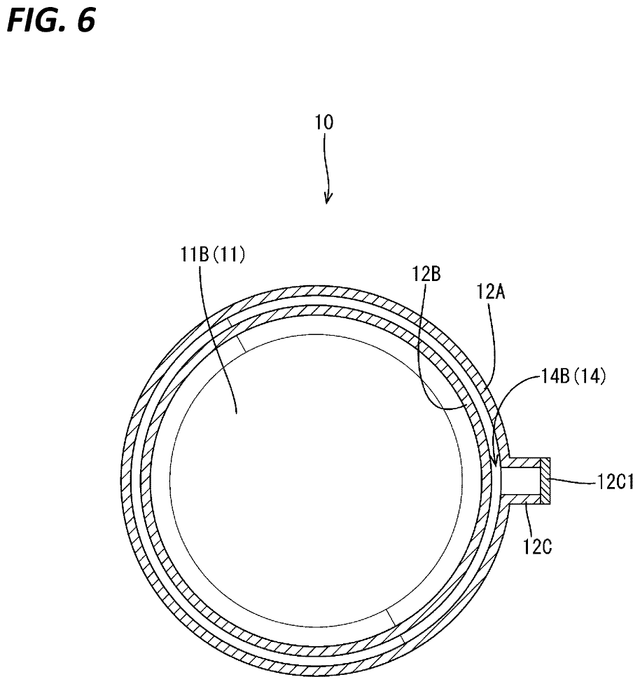

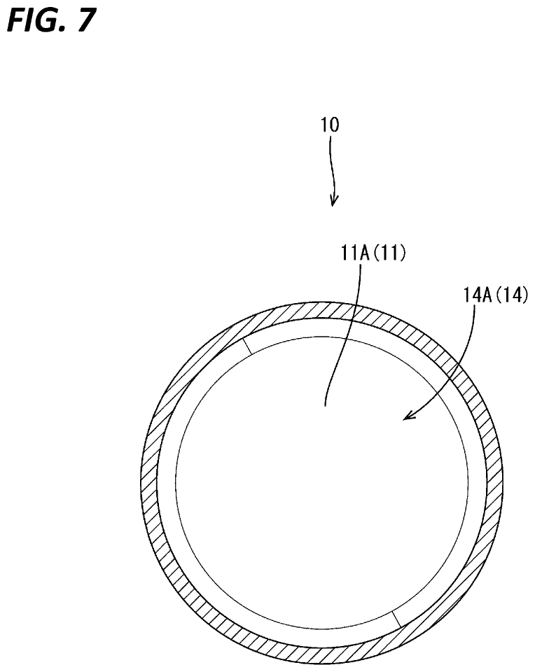

As shown in FIG. 4, a sealed space 14 is formed inside the bottom 11 and the circumferential wall portion 12. In detail, the sealed space 14 is constituted by a first space 14A formed inside the bottom 11 and a second space 14B that is in communication with the first space 14A and is formed inside the circumferential wall portion 12. The sealed space 14 is depressurized. The first space 14A is a space formed between the first wall 11A and the second wall 11B. As shown in FIG. 7, the first space 14A extends in the in-plane direction. As shown in FIGS. 5 and 6, the second space 14B is a space formed by the outer wall 12A, the inner wall 12B, and the tubular portion 12C. The second space 14B is substantially annular viewed from the first direction.

### Working Fluid 15

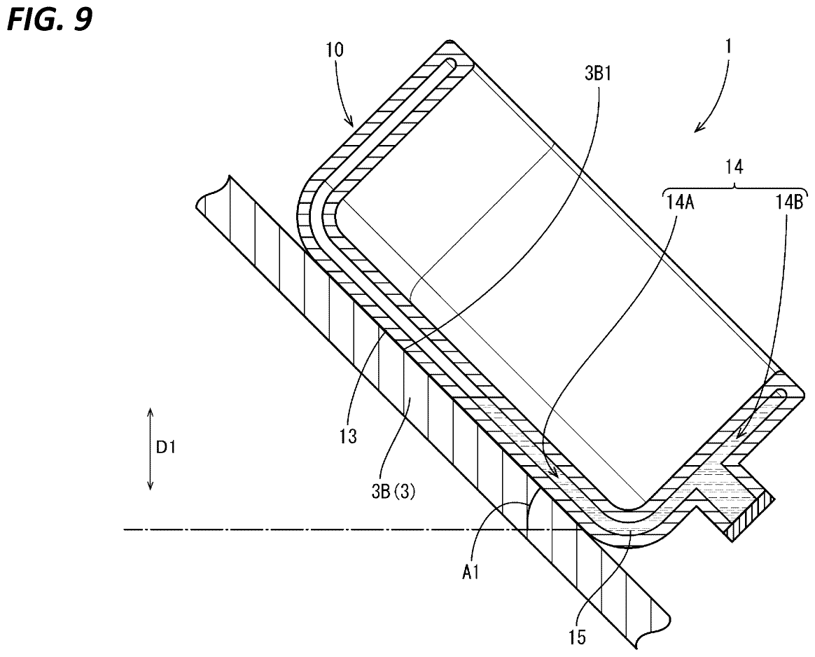

As shown in FIGS. 8 and 9, the sealed space 14 is filled with a working fluid 15 (not shown in FIGS. 4 to 7). For example, water, antifreeze, or the like can be used as the working fluid 15. A part of the sealed space 14 is filled with the working fluid 15 in a liquid state. Hereinafter, unless otherwise mentioned, “working fluid 15” is intended to be in a liquid state.

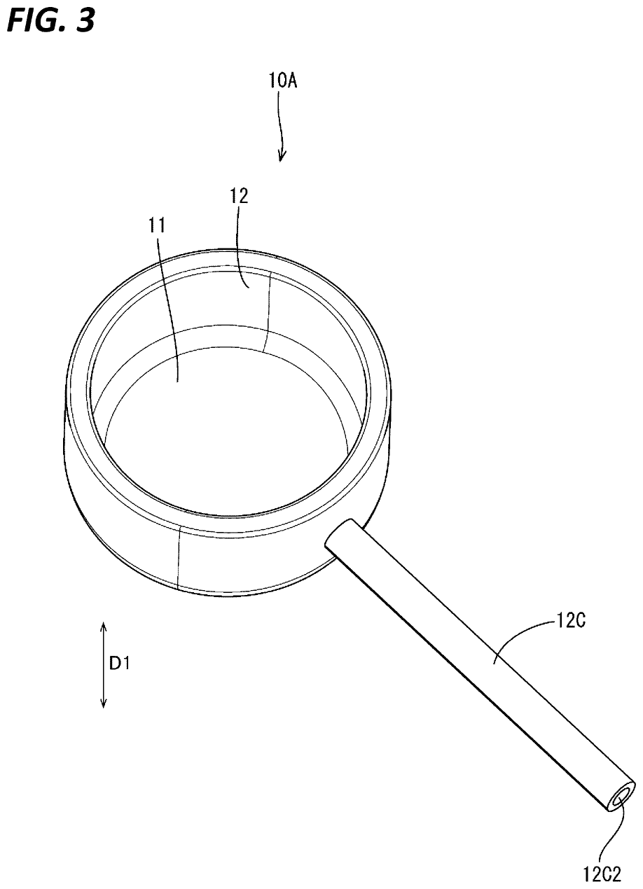

The heat pipe 10 can be manufactured using a 3D printer, for example. First, an unsealed body 10A as shown in FIG. 3 is formed. The unsealed body 10A is the heat pipe 10 before the sealed space 14 is formed, that is, before the tubular portion 12C is sealed. An opening 12C2 of the tubular portion 12C of the unsealed body 10A is connected to a vacuum pump via a hose, for example, and the inner space of the unsealed body 10A (corresponding to the later-described sealed space 14) is decompressed. Then, the working fluid 15 is injected into the inner space of the unsealed body 10A from the tubular portion 12C via a hose or the like. Finally, the tubular portion 12C is clamped to form the sealing part 12C1, and the production of the heat pipe 10 is complete (see FIG. 8).

As shown in FIG. 8, when the electrical device 1 is disposed on a horizontal plane (plane perpendicular to the vertical direction), the contact surface 13 is arranged parallel to the horizontal plane. The first direction D1 is an up-down direction (vertical direction), one side of the first direction D1 is upward, and the other side of the first direction D1 is downward. Therefore, the circumferential wall portion 12 is arranged above the bottom 11. The working fluid 15 in a liquid state is placed unevenly in the first space 14A and biased toward the first wall 11A side due to gravity. On the other hand, a greater part of the second space 14B is filled with a depressurized gas including the working fluid 15 in a gaseous state.

When heat is generated by the relay 2 due to the use of the electrical device 1, the heat generated from relay 2 is transferred to the busbar 3. The heat is then transferred from the contact surface 13, which is in contact with the outer surface 3B1 of the mounting part 3B, to the heat pipe 10. Here, the working fluid 15 is placed unevenly and biased toward the first wall 11A having the contact surface 13, so that the working fluid 15 easily vaporizes. Therefore, the vaporization of the working fluid 15 facilitates dissipation of the heat of the relay 2 through the busbar 3. Once having vaporized, the working fluid 15 rises from the first space 14A and moves into the second space 14B. The vaporized working fluid 15 is cooled and condensed (liquefied) in the second space 14B by heat exchange with ambient air through the circumferential wall portion 12. The working fluid 15 liquefied again moves down to the first space 14A due to gravity. As a result of the repeated vaporization and condensation of the working fluid 15, the busbar 3 and thus the relay 2 can be cooled.

As shown in FIG. 9, when the electrical device 1 is disposed in a plane that has an inclination angle A1 with respect to the horizontal plane (dashed-dotted line in FIG. 9) (for example, when the vehicle in which the electrical device 1 is installed is in an inclined position on a slope or the like), the contact surface 13 is arranged at the inclination angle Al with respect to the horizontal plane and a part of the working fluid 15 in liquid state moves into the second space 14B. However, another part of the working fluid 15 in liquid state still remains in the first space 14A. Therefore, even when the electrical device 1 is inclined at the inclination angle A1 with respect to the horizontal plane, the relay 2 can be efficiently cooled by vaporization of the working fluid 15.

Also, the bottom 11 is circular when viewed from the first direction D1, and the circumferential wall portion 12 extends from the outer edge of the bottom 11 in the first direction D1. Therefore, if the inclination angle A1 is the same, substantially the same amount of working fluid 15 (that may differ by the volume inside the tubular portion 12C) will be placed in at least a part of the first space 14A, regardless of which direction the electrical device 1 is inclined with respect to the horizontal plane.

The relationship as to how much extent the working fluid 15 fills the first space 14A for the inclination angle A1 can be set by adjusting, for example, the volume ratio of the first space 14A to the second space 14B, or the volume ratio of the working fluid 15 to the sealed space 14. For example, when the inclination angle A1 is 45° or less, the first space 14A may be set so that at least a portion (e.g., one-third) of the first space 14A is filled with the working fluid 15.

### Functions and Effects of Embodiment 1

(1-1) The heat pipe 10 according to Embodiment 1 is a heat pipe 10 configured to be disposed inside the electrical device 1 and to be attached to an object (busbar 3), the heat pipe 10 including: a bottom 11 that has a contact surface 13 configured to come into contact with the object; a circumferential wall portion 12 that extends from the bottom 11 in a direction (first direction D1) that intersects the contact surface 13; a sealed space 14 formed inside the bottom 11 and the circumferential wall portion 12; and a working fluid 15 placed to fill a part of the sealed space 14.

According to this configuration, even if the electrical device 1 is inclined, at least a part of the working fluid 15 is easily placed to come into contact with the bottom 11, thus facilitating heat transfer from the object to the working fluid 15. Therefore, the heat of the object can be efficiently dissipated by vaporization of the working fluid 15.
(1-2) In Embodiment 1, the bottom 11 is circular and the circumferential wall portion 12 extends from an outer edge of the bottom 11.

With this configuration, at least a part of the working fluid 15 is easily placed to come into contact with the bottom 11, regardless of the direction in which the electrical device 1 is inclined. Therefore, the heat of the object can be dissipated more efficiently.
(1-3) In Embodiment 1, the circumferential wall portion 12 is located above the bottom 11 when the electrical device 1 is disposed on a horizontal plane.

With this configuration, it is possible to maximize the volume of the working fluid 15 placed to come into contact with the bottom 11 when the electrical device 1 is not inclined. Therefore, the heat of the object can be dissipated more efficiently.
(1-4) The electrical device 1 according to Embodiment 1 includes: the heat pipe 10; a heat generation component (relay 2); and a busbar 3 that is connected to the heat generation component and to which the heat pipe 10 is attached.

With this configuration, it is possible to efficiently dissipate heat transferred from the heat generation component to the busbar 3.

### Embodiment 2

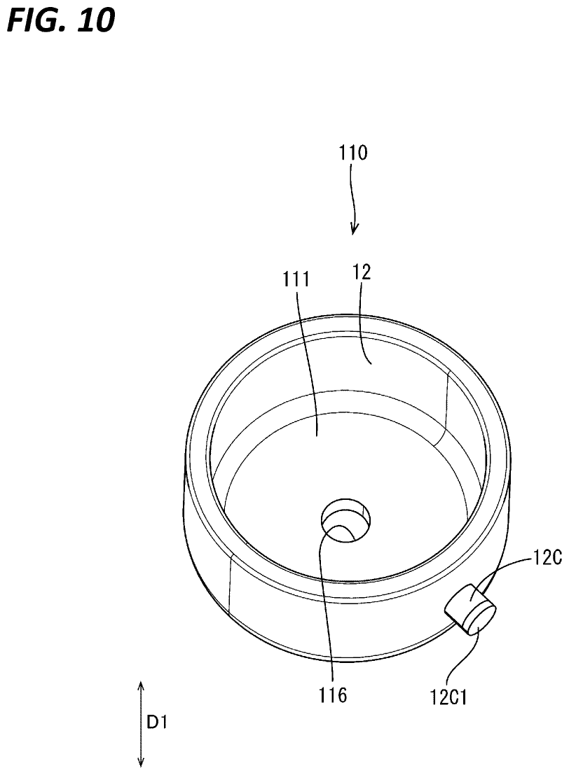

The following will describe Embodiment 2 of the present disclosure with reference to FIGS. 10 to 13. A heat pipe 110 and an electrical device 101 according to Embodiment 2 are configured in the same manner as in Embodiment 1, except for the configuration of a bottom 111, so the description of the components identical to those in Embodiment 1 as well as their functions and effects will be omitted.

### Insertion Hole 116

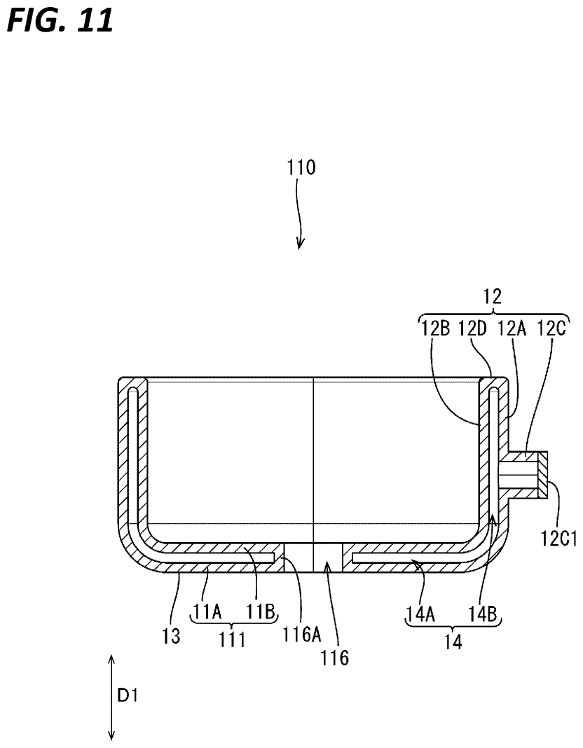

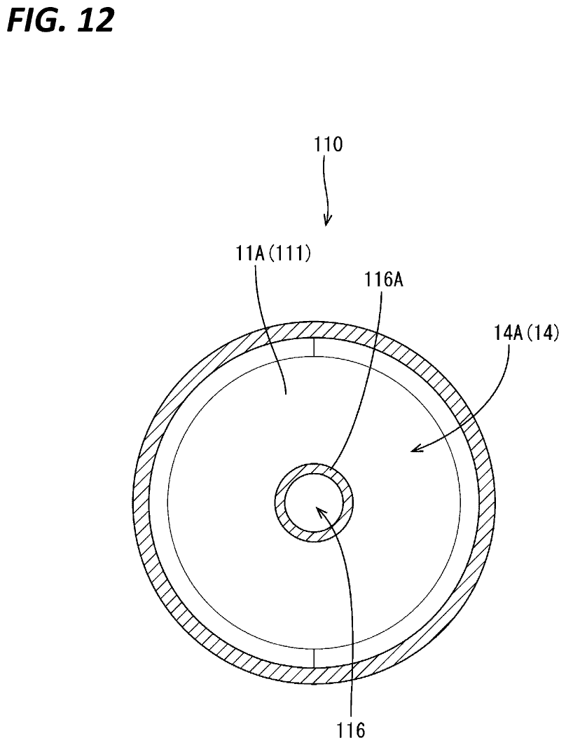

As shown in FIG. 10, an insertion hole 116 is formed in the center of the bottom 111 of the heat pipe 110. The insertion hole 116 passes through the bottom 111 in the first direction D1. As shown in FIG. 11, an inner wall 116A constituting the insertion hole 116 connects the first wall 11A and the second wall 11B of the bottom 111. As shown in FIG. 12, the inner wall 116A is annular when viewed in the first direction D1.

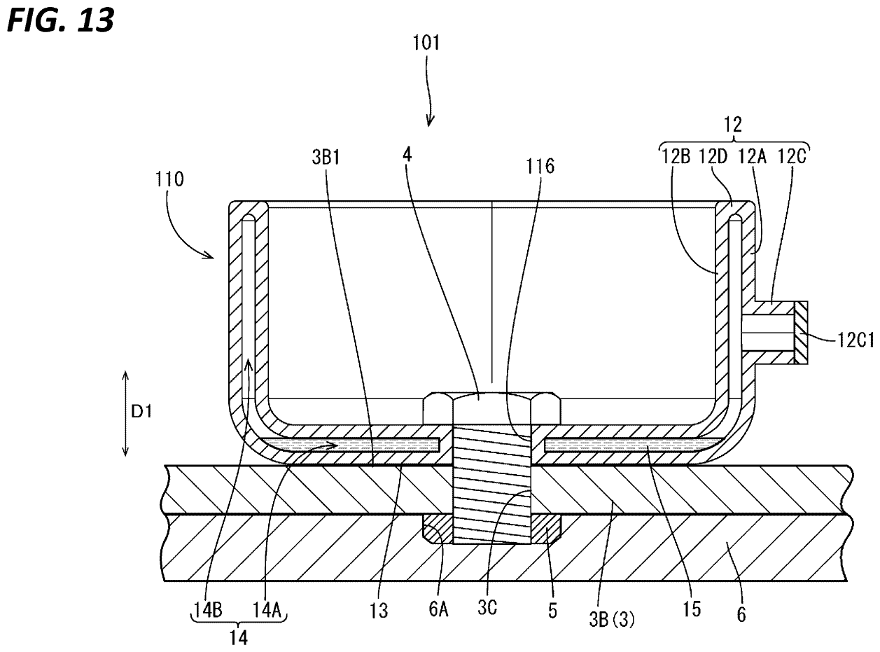

As shown in FIG. 13, a bolt 4 for attaching the heat pipe 110 to the busbar 3 is passed through the insertion hole 116. The bolt 4 is passed through a through hole 3C formed in the busbar 3 and is fastened to a nut 5. The nut 5 is housed in a nut housing 6A of a case 6.

### Functions and Effects of Embodiment 2

(2-1) In Embodiment 2, the bottom 111 has the insertion hole 116 for bolting the heat pipe 110 to an object.

With this configuration, it is possible to fix the heat pipe 110 to an object by bolting.

### Embodiment 3

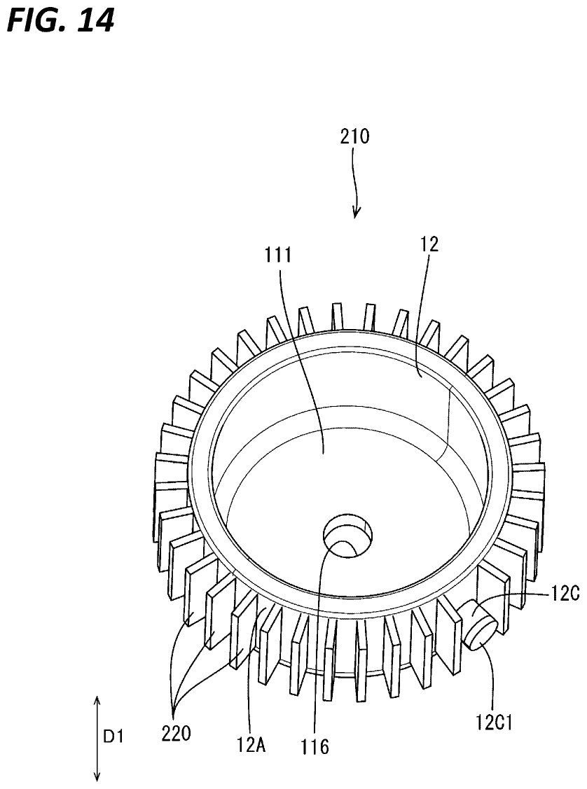

The following will describe Embodiment 3 of the present disclosure with reference to FIGS. 14 to 16. A heat pipe 210 according to Embodiment 3 is configured in the same manner as in Embodiment 2, except for the heat pipe 210 having fins 220, so the description of the components identical to those in Embodiment 2 as well as their functions and effects will be omitted.

### Fin 220

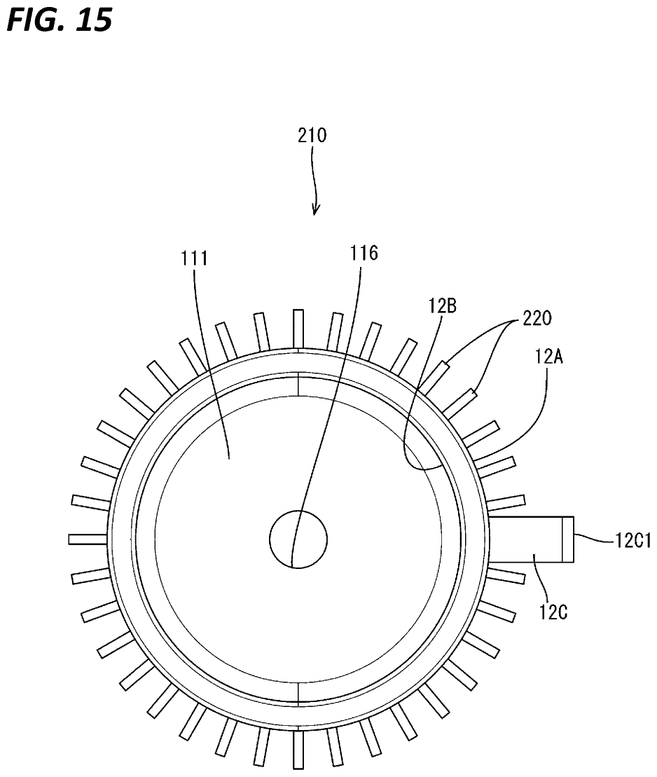

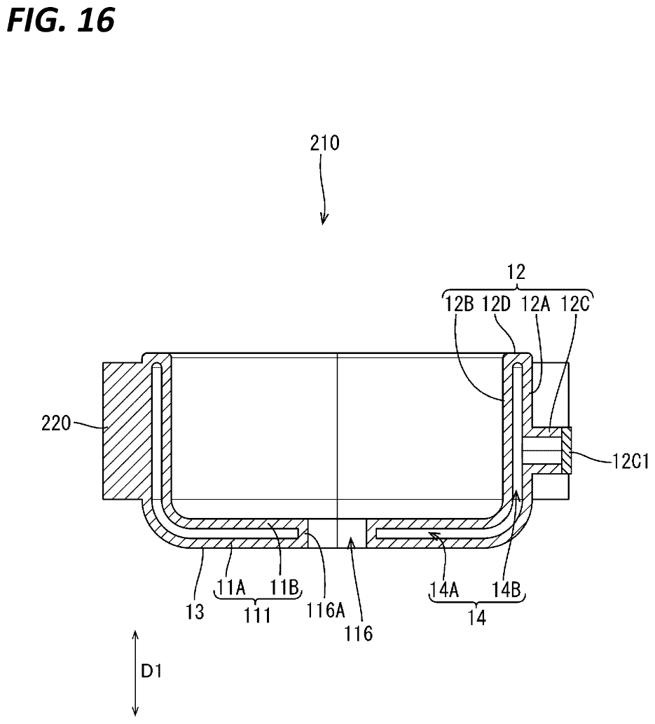

As shown in FIG. 14, the heat pipe 210 includes the plurality of fins 220 that extend from the outer wall 12A of the circumferential wall portion 12. The fins 220 are plate shaped. As shown in FIG. 15, the fins 220 extend away from the inner wall 12B in the in-plane direction. As shown in FIG. 16, there is no space inside each fin 220 that is in communication with the second space 14B. Providing the fins 220 can increase the surface area of the heat pipe 210 that is in contact with ambient air. This results in an improvement in efficiency of heat exchange between the heat pipe 210 and the ambient air, making it easy to dissipate the heat to ambient air.

### Functions and Effects of Embodiment 3

(3-1) The heat pipe 210 according to Embodiment 3 further includes the plurality of fins 220 that extend from the circumferential wall portion 12.

With this configuration, providing the fins 220 facilitates dissipation of heat from the heat pipe 210 to ambient air.

### Embodiment 4

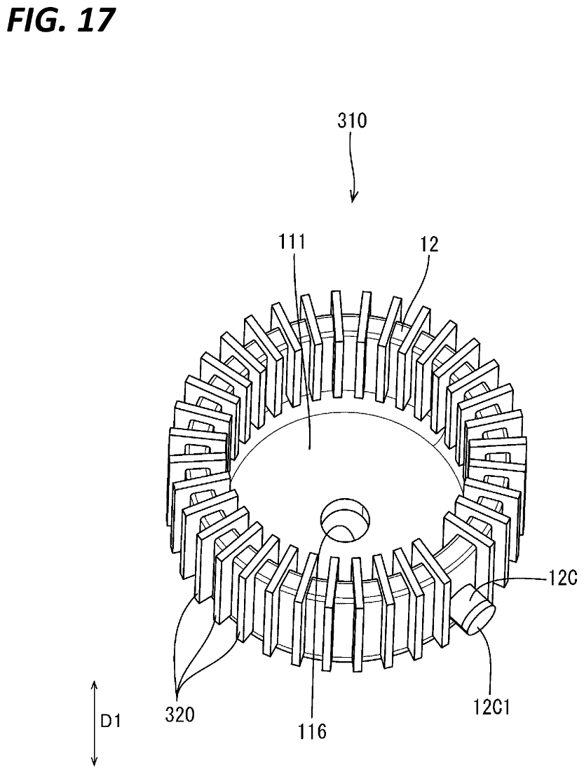

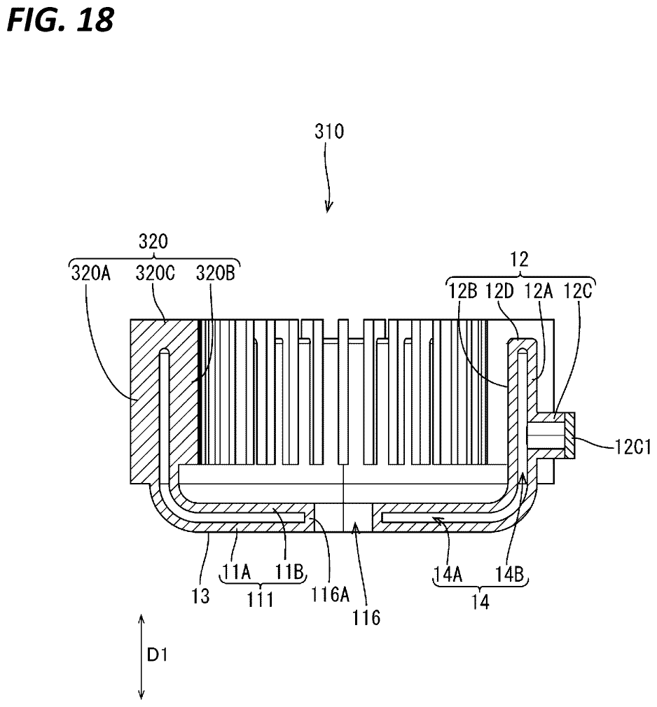

The following will describe Embodiment 4 of the present disclosure with reference to FIGS. 17 to 18. A heat pipe 310 according to Embodiment 4 includes fins 320 that have a shape different from the fins 220 of Embodiment 3. The configuration of the heat pipe 310 is configured in the same manner as in Embodiment 3, except for the shape of the fins 320, so the description of the components identical to those in Embodiment 3 as well as their functions and effects will be omitted.

### Fin 320

As shown in FIG. 17, the heat pipe 310 includes the plurality of fins 320 that extend from the circumferential wall portion 12. The fins 320 are plate shaped. As shown in FIG. 18, each of the fins 320 includes a first portion 320A that extends from the outer wall 12A, a second portion 320B that extends from the inner wall 12B, and a third portion 320C that extends from the connection end 12D and connects the first portion 320A and the second portion 320B.

### Embodiment 5

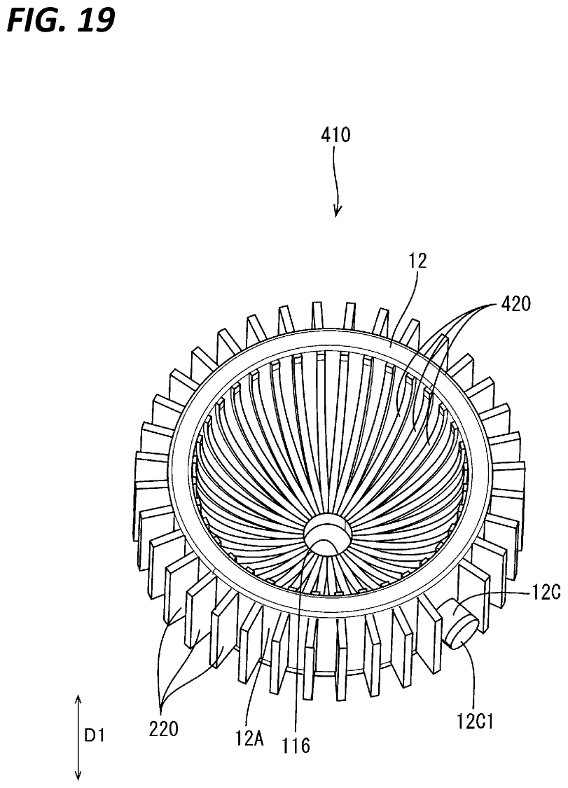

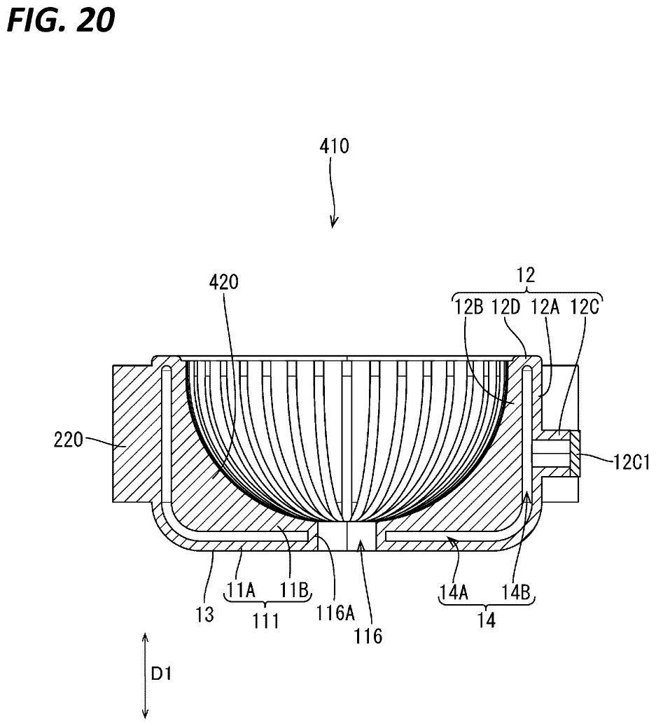

The following will describe Embodiment 5 of the present disclosure with reference to FIGS. 19 to 20. A heat pipe 410 according to Embodiment 5 further includes fins 420, in addition to the fins 220 of Embodiment 3. The configuration of the heat pipe 410 is configured in the same manner as in Embodiment 3, except for the shape of the fins 420, so the description of the components identical to those in Embodiment 3 as well as their functions and effects will be omitted.

### Fin 420

As shown in FIG. 19, the heat pipe 410 includes the plurality of fins 420 formed inside the circumferential wall portion 12. The fins 420 are plate shaped. As shown in FIG. 20, each of the fins 420 extends from the inner wall 12B of the circumferential wall portion 12 and the second wall 11B of the bottom 111. The fin 420 is formed so that its dimension in the first direction D1 decreases toward the insertion hole 116 from the circumferential wall portion 12 in the in-plane direction. The end face of the fin 420 on one side in the first direction D1 (upper side in the illustration in FIG. 20) constitutes a part of a curved face of a mortar shape. In other words, the end face of the fin 420 on one side in the first direction D1 is arc-shaped in cross-section in a manner such that it is curved in a direction approaching the circumferential wall portion 12 and the bottom 111.

### Other Embodiments

Embodiments 1 to 5 above can be modified and implemented as follows. Embodiments 1 to 5 above and the following modifications can be implemented in combination as long as no technical contradiction arises.
In Embodiment 1 above, the relay 2 is taken as an example of a heat generation component, but the heat generation member may be, for example, a resistor, coil, capacitor, fuse, diode, IC (Integrated Circuit), or switching element such as a FET (Field Effect Transistor).
In Embodiment 1 above, the busbar 3 connected to a heat generation member (relay 2) is taken as an example of an object to which the heat pipe 10 is attached, but the heat pipe may be directly attached to the heat generation member, for example.
In Embodiments 1 to 5, the bottom 11, 111 is circular, but the bottom may be polygonal or elliptical, for example.
In Embodiments 1 to 5 above, the circumferential wall portion 12 extends from the outer edge of the bottom 11, 111, but the circumferential wall portion may extend from a portion on an inner side of the outer edge of the bottom. Also, the circumferential wall portion may not be cylindrical.
In Embodiments 1 to 5 above, the circumferential wall portion 12 extends in a direction (first direction D1) orthogonal to the contact surface 13 of the bottom 11, 111, but the direction in which the circumferential wall portion extends need not be orthogonal to the contact surface. It is sufficient that the direction in which the circumferential wall portion extends intersects the contact surface.
The fins of the present disclosure may be different from the fins 220, 320, and of Embodiments 3 to 5 above. For example, the shape and number of the fins, as well as the arrangement of the fins relative to the circumferential wall portion may be changed as needed.

### LIST OF REFERENCE NUMERALS

1, 101: Electrical device
2: Relay
2A: Body part
2B: Terminal part
3: Busbar
3A: Connection part
3B1: Outer surface
3B: Mounting part
3C: Through hole
4: Bolt
5: Nut
6: Case
6A: Nut housing
10, 110, 210, 310, 410: Heat pipe
10A: Unsealed body
11, 111: Bottom
11A: First wall
11B: Second wall
12: Circumferential wall portion
12A: Outer wall
12B: Inner wall
12C1: Sealed portion
12C2: Opening
12C: Tubular portion
12D: Connection end
13: Contact surface
14: Sealed space
14A: First space
14B: Second space
15: Working fluid
116: Insertion hole
116A: Inner wall
220, 320, 420: Fin
320A: First portion
320B: Second portion
320C: Third portion
A1: Inclination angle
D1: First direction

1. A heat pipe configured to be disposed inside an electrical device and to be attached to an object, the heat pipe comprising:
a bottom that has a contact surface configured to come into contact with the object;
a circumferential wall portion that extends from the bottom in a direction that intersects the contact surface;
a sealed space formed inside the bottom and the circumferential wall portion; and
a working fluid placed to fill a part of the sealed space.

2. The heat pipe according to claim 1, further comprising a plurality of fins that extend from the circumferential wall portion.

3. The heat pipe according to claim 1,
wherein the bottom is circular, and
the circumferential wall portion extends from an outer edge of the bottom.

4. The heat pipe according to claim 1,
wherein the bottom has an insertion hole for bolting the heat pipe to the object.

5. The heat pipe according to claim 1,
wherein the circumferential wall portion is located above the bottom when the electrical device is disposed on a horizontal plane.

6. An electrical device comprising:
the heat pipe according to claim 1;
a heat generation component; and
a busbar that is connected to the heat generation component and to which the heat pipe is attached.
